(19) United States
(12) Patent Application Publication
(10) Pub. No.: US 2012/0145232 A1
(43) Pub. Date: Jun. 14, 2012

(54) SOLAR CELL HAVING IMPROVED REAR CONTACT

(76) Inventors: Yu Kyung KIM, Hwaseong-si (KR); Dong Seop Kim, Seongnam-si (KR)

(21) Appl. No.: 13/091,015

(22) Filed: Apr. 20, 2011

(30) Foreign Application Priority Data
Dec. 10, 2010 (KR) 10-2010-0126096

(51) Int. Cl. H01L 31/0224

(52) U.S. Cl. 136/256

(57) ABSTRACT

Provided is a solar cell including: a semiconductive base layer having a first conductivity type; a semiconductive emitter layer disposed on top of the base layer and having a second conductivity type opposite to the first conductivity type; a front electrode disposed on top of the emitter layer; a passivation layer disposed under the base layer and including a contact hole exposing the base layer; and a rear electrode disposed under the passivation layer and connected with the base layer through the contact hole, wherein the rear electrode comprises a silicon (Si)-aluminum (Al) eutectic alloy powder.

### CROSS-REFERENCE TO RELATED APPLICATION

This application claims priority to and the benefit of Korean Patent Application No. 10-2010-0126096 filed in the Korean Intellectual Property Office on Dec. 10, 2010, the entire contents of which application are incorporated herein by reference.

### BACKGROUND

(a) Field of Disclosure

The present disclosure of invention relates to a solar cell.

(b) Description of Related Technology

Solar cells are devices which convert solar light energy into electrical energy using the photoelectric effect. Solar cells are important as clean energy or next-generation energy that can replace fossil fuel energy where the latter may cause greenhouse effects due to discharge of CO₂. Nuclear energy has been proposed as a solution but it often contaminates the Earth environment much as does air pollution due to the radioactive waste problem for example.

The typical solar cell includes a semiconductor substrate including a p-type semiconductor and an n-type semiconductor and electrodes disposed above and below the semiconductor substrate. The solar cell can serve as an independent and external energy source for a variety of electronic devices by absorbing received solar light energy in a photoactive layer thereof so as to generate electron-hole pairs (EHPs) in its semiconductor body. The generated electrons and holes respectively move (e.g., drift) to the n-type semiconductor region (where electrons are majority carriers) and to the p-type semiconductor region (where holes are majority carriers), to be thereafter collected in the electrodes as produced electrical current.

Solar cells which use silicon as the light absorbing layer may be classified into crystalline wafer type solar cells and thin film type (amorphous and polycrystalline) solar cells. Other examples of solar cells may include compound thin film solar cells using CIGS (CuInGaSe2) or CdTe, a III-V group solar cell, a dye-sensitized solar cell, or an organic compound solar cell.

In the case of the crystalline wafer type solar cells, after an oxide based insulating layer is deposited on a rear side of the wafer, a rear electrode is formed on the insulating layer, for example one using aluminum. In this case, when the aluminum and the crystalline wafer are to electrically contact each other, this is done by forming contact holes through the insulating layer. Sometimes however, a void is generated on the contact surface such that the efficiency of the solar cell is deteriorated.

The above information disclosed in this Background section is only for enhancement of understanding of the background of the technology and therefore it may contain information that does not form the prior art as known to persons of ordinary skill in the art.

### SUMMARY

The present teachings provide a solar cell having advantages of preventing the generation of the voids in the contact surface between a rear electrode and a crystalline substrate of a solar cell.

An exemplary embodiment in accordance with the present disclosure comprises a solar cell including: a semiconductive base layer of a first conductivity type; a semiconductive emitter layer of an opposed second conductivity type and disposed on top of the base layer; a front electrode disposed on top of the emitter layer; a passivation layer disposed under the base layer and including a contact hole exposing the base layer; and a rear electrode disposed under the passivation layer and connected with the base layer through the contact hole, wherein the rear electrode comprises a silicon (Si)-aluminum (Al) eutectic alloy powder.

The rear electrode may further comprise a glass frit.

The silicon (Si)-aluminum (Al) eutectic alloy powder may be composed of silicon of about 12 at % and aluminum of about 88 at %.

The glass frit may be made of any one of lead silicate glass, bismuth (Bi)-based glass, and lithium-based glass.

The passivation layer may be made of a silicon nitride-based compound and may have a thickness of 2000 to 5000 Å.

The solar cell may further include a buffer layer having an embedded negative charge and interposed between the base layer and the passivation layer.

The buffer layer may be made of any one of aluminum oxide (Al₂O₃) or an aluminum oxide nitride (AlON) and may have a thickness of 50 to 500 Å.

The solar cell may further include an aluminum impurity layer disposed in the base layer and contacting the rear electrode.

The rear electrode may further comprise boron and a glass frit.

Using the exemplary embodiments of the present teachings, the generation of voids between the rear electrode and the base layer can be prevented, thereby improving characteristics of the solar cell by forming the rear electrode using the silicon (Si)-aluminum (Al) eutectic alloy powder composed of silicon of 12 at % and aluminum of 88 at %.

### BRIEF DESCRIPTION OF THE DRAWINGS

FIG. 1 is a cross-sectional view illustrating a solar cell according to an exemplary embodiment of the present disclosure.

FIGS. 2 and 3 are diagrams sequentially showing a method for manufacturing a solar cell of FIG. 1.

FIG. 4 is a table comparing an exemplary embodiment of the present disclosure with other comparative examples by measuring open circuit voltage, fill factor, efficiency, and resistance.

### DETAILED DESCRIPTION

The present teachings will be described more fully hereinafter with reference to the accompanying drawings, in which exemplary embodiments are shown. As those skilled in the art would realize from the teachings, the described embodiments may be modified in various different ways, all without departing from the spirit or scope of the present disclosure. On the contrary, the embodiments described herein are intended to provide full understanding of the here provided teachings and thus fully transfer the spirit and scope of the present teachings to those skilled in the relevant art.

In the drawings, the thickness of layers, films, panels, regions, etc., are exaggerated for clarity. When a layer is referred to as being “on” another layer or a substrate, it can be directly on another layer or the substrate or a third intervening layer may also be present. Throughout the specification, like reference numerals refer to like elements.

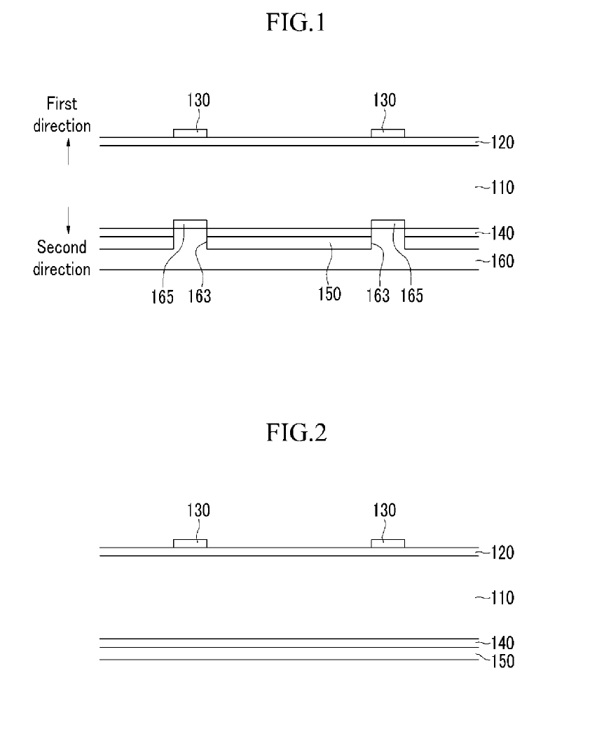

FIG. 1 is a cross-sectional view illustrating a solar cell according to an exemplary embodiment of the present disclosure.

As shown in FIG. 1, a second carrier conducting or emitting layer 120 is provided at the top of the configure and it (120) includes a semiconductor doped with a second conductive type of impurity. A first charge carrier conducting layer 110 of a corresponding first conductive type is disposed under the emitter layer 120. The top of the solar cell faces in a first direction, for example towards the Sun. The first charge carrier conducting or base layer 110 is provided below and it includes a semiconductor doped with a first conductive type impurity. In one embodiment, a P-type silicon substrate is used as the base layer 110 and the P-type silicon substrate is doped by one or more impurities such as boron (B), gallium (Ga), indium (In), or the like. In the one embodiment, the oppositely doped emitter layer 120 is doped by one or more impurities such as phosphorus (P), arsenic (As), stibium (Sb), or the like. In this case, a P-N junction is formed between the base layer 110 and the emitter layer 120. Alternatively, an N-type silicon substrate may be used as the base layer 110. Alternatively, an undoped or intrinsic semiconductor layer may be interposed between the P and N layers so as to define a PIN structure.

A front electrode 130 is disposed on the first direction facing major surface of the emitter layer 120. The front electrode 130 may be made of a low-resistance metal such as silver (Ag) and it may be designed as a grid pattern, such that a shadowing loss and a surface resistance may be decreased.

Further, an insulating layer acting as an anti-reflective coating (ARC) in which reflectance of light is decreased may be provided at the top of the front surface of the illustrated solar cell and it may be selectivity structured for maximizing trapping of a predetermined light wavelength region. In one embodiment, the ARC layer (not shown) is formed between the emitter layer 120 and the front electrodes layer 130 and contact holes are provided for electrically connecting the front electrodes 130 to the emitter layer 120.

A buffer layer 140 is disposed on the second direction facing major surface of the base layer 110. The buffer layer 140 is made of aluminum oxide (Al₂O₃) or an aluminum oxide nitride (AlON) having a negative charge and has a thickness of 50 to 500 Å. The buffer layer 140 may function to decrease a parasitic short-circuiting current in the solar cell to thereby increase the efficiency of the solar cell where this is done by repelling minority carriers (e.g., electrons if 110 is P-type) generated in the base by light energy, where the buffer layer 140 is implanted with a fixed negative charge. The repelled minority carriers (e.g., electrons if 110 is P-type) are then transmitted to the front electrode 130 for desired gathering thereby.

A passivation layer 150 is disposed on the second direction facing major surface of the buffer layer 140. The passivation layer 150 is made of a silicon nitride (SiN)-based compound and has a thickness of 2000 to 5000 Å. When the buffer layer 140 is formed by using a thin film deposition process, the film characteristic may be deteriorated due to temporal and environmental influences such that it is not faithful to the minority carrier repelling role thereof. In this case, the passivation layer 150 acts to compensate for the problem. Rear surface contact holes 163 are formed at desired positions along and through the buffer layer 140 and the passivation layer 150.

A rear electrode 160 is disposed on the second direction facing major surface of the passivation layer 150. The rear electrode 160 is made of a silicon (Si)-aluminum (Al) eutectic alloy paste composition composed of a silicon (Si)-aluminum (Al) eutectic alloy powder, a glass frit, and a solvent.

The silicon (Si)-aluminum (Al) eutectic alloy powder is composed of silicon of about 12 atomic % content and aluminum of about 88 atomic % content and the combined content of this Si(≈12% at) Al(≈88% at) alloy is in the range of about 75 to 80 wt % with respect to the total mass or weight of the silicon (Si)-aluminum (Al) eutectic alloy paste composition. Here, eutectic alloy means a mixed alloy composition in which two components (e.g., Si and Al) are fully dissolved within and homogenously mixed in a liquid state host.

That is, the liquid alloy particles of the silicon (Si)-aluminum (Al) eutectic alloy powder are composed of about silicon of 12 at % and aluminum of 88 at %.

The glass frit, which is believed to operate to improve adhesion of the paste 160 with respect to the adjacent passivation layer 150, is made of lead silicate glass, bismuth (Bi)-based glass, lithium-based glass, or the like and the content thereof is in the range of 2 to 8 wt % with respect to a total weight of the silicon (Si)-aluminum (Al) eutectic alloy paste composition.

As shown in FIG. 1, the contact holes 163 extend beyond the passivation layer 150 and the buffer layer 140 to penetrate into the base layer 110. An aluminum impurity layer 165 is formed (deposited) at the penetrated portions of the base layer 110 exposed by the contact hole 163. The aluminum impurity layer 165, which provides more aluminum than that of the rear electrode 160 for contacting the base layer 110, is believed to operate to prevent the recombination of parasitic electrons and majority holes in that regions and has a back surface field (BSF) effect for improving the collection efficiency of the generated majority carriers (e.g., holes).

Because the Si/Al based eutectic alloy paste composition 160 is a fluidic one, it tends to fill substantially all voids and therefore the generation of voids between the rear electrode composition 160 and the base layer 110 can be prevented by forming the rear electrode 160 using the electrically conductive fluidic contact medium such as the here disclosed silicon (Si)-aluminum (Al) eutectic alloy powder composed of silicon of 12 at % and aluminum of 88 at %.

Additionally, boron (B) may be further included in the silicon (Si)-aluminum (Al) eutectic alloy paste composition forming the rear electrode 160. That is, the silicon (Si)-aluminum (Al) eutectic alloy paste composition may include the silicon (Si)-aluminum (Al) eutectic alloy powder, the glass frit, the added boron, and a solvent which enhances the fluidic nature of the paste.

@When the boron (B)-included silicon (Si)-aluminum (Al) eutectic alloy paste composition is used, the concentration of the boron (B) is increased in the aluminum impurity layer 165 such that the recombination of electrons is prevented and the back surface field (BSF) effect improving the collection efficiency of the generated carrier is further increased.

When the boron (B) is included in the silicon (Si)-aluminum (Al) eutectic alloy paste composition, the content of the boron (B) is in the range of 0.05 to 20 wt % with respect to a total weight of the silicon (Si)-aluminum (Al) eutectic alloy paste composition. In this case, the silicon (Si)-aluminum (Al) eutectic alloy powder is composed of silicon of 12 at % and aluminum of 88 at %, the content of the silicon (Si)-aluminum (Al) eutectic alloy powder is in the range of 50 to 80 wt % with respect to a total weight of the silicon (Si)-aluminum (Al) eutectic alloy paste composition, and the content of the glass frit is in the range of 0.5 to 10 wt % with respect to a total weight of the silicon (Si)-aluminum (Al) eutectic alloy paste composition.

Hereinafter, a method for manufacturing the solar cell according to the exemplary embodiment will be described in detail with reference to FIGS. 2 and 3 and FIG. 1.

As shown in FIG. 2, after an emitter layer 120 is formed on the first direction facing major surface of a base layer 110, a front electrode 130 is formed on the first direction facing major surface of the emitter layer 120.

The base layer 110 is formed of a P-type silicon substrate and the emitter layer 120 is formed of a N-type silicon substrate doped by the impurity such as phosphorus (P), arsenic (As), stibium (Sb), or the like.

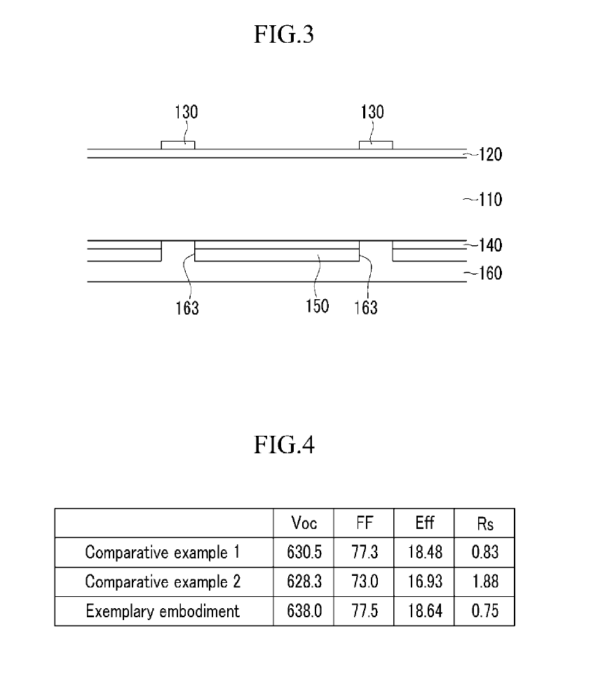

Thereafter, as shown in FIG. 3, a buffer layer 140 is formed by depositing a material having a negative fixed charge embedded therein such as aluminum oxide (Al₂O₃) or aluminum oxide nitride (AlON) on the second direction facing major surface of the base layer 110. In this case, the buffer layer 140 has a thickness of 50 to 500 Å.

A passivation layer 150 is formed by depositing the silicon nitride-based compound on the second direction facing major surface of the buffer layer 140. In this case, the passivation layer 150 has a thickness of 2000 to 5000 Å.

Thereafter, after one or more contact holes 163 exposing the rear surface of the base layer 110 using a laser are formed through the buffer layer 140 and the passivation layer 150 (where the aluminum impurity layer 165 will be created later), a rear electrode 160 is formed by coating and then firing a silicon (Si)-aluminum (Al) eutectic alloy paste composition on the rear surface of the base layer 110 exposed by the passivation layer 150 and the contact hole 163, using a screen printing process or the like.

The silicon (Si)-aluminum (Al) eutectic alloy paste composition is composed of a silicon (Si)-aluminum (Al) eutectic alloy powder, a glass frit, and a solvent. More specifically, the silicon (Si)-aluminum (Al) eutectic alloy powder is composed of silicon of 12 at % and aluminum of 88 at % and the content thereof is in the range of 75 to 80 wt % with respect to a total weight of the silicon (Si)-aluminum (Al) eutectic alloy paste composition.

The glass frit is made of lead silicate glass, bismuth (Bi)-based glass, lithium-based glass, or the like and the content thereof is in the range of 2 to 8 wt % with respect to a total weight of the silicon (Si)-aluminum (Al) eutectic alloy paste composition.

The firing is performed at a temperature of 660° C. (melting point of aluminum) or more for a short time and particularly, maintained at a temperature of 700° C. or more for 2 to 3 seconds. In this case, the silicon (Si)-aluminum (Al) eutectic alloy powder is diffused into the rear surface of the base layer 110 exposed by the contact hole 163 while being dissolved and then as shown in FIG. 1, an aluminum impurity layer 165 is formed due to reaction of the fired silicon (Si)-aluminum (Al) eutectic alloy powder with the exposed base layer 110.

In addition, the silicon (Si)-aluminum (Al) eutectic alloy paste composition may be composed of a silicon (Si)-aluminum (Al) eutectic alloy powder, a boron, a glass frit, and a solvent. More specifically, when the boron (B) is included in the silicon (Si)-aluminum (Al) eutectic alloy paste composition, the content of the boron (B) is in the range of 0.05 to 20 wt % with respect to a total weight of the silicon (Si)-aluminum (Al) eutectic alloy paste composition. In this case, the silicon (Si)-aluminum (Al) eutectic alloy powder is composed of silicon of 12 at % and aluminum of 88 at %, the content of the silicon (Si)-aluminum (Al) eutectic alloy powder is in the range of 50 to 80 wt % with respect to a total weight of the silicon (Si)-aluminum (Al) eutectic alloy paste composition, and the content of the glass frit is in the range of 0.5 to 10 wt % with respect to a total weight of the silicon (Si)-aluminum (Al) eutectic alloy paste composition.

When the boron (B)-included silicon (Si)-aluminum (Al) eutectic alloy paste composition is used, the concentration of the boron (B) is increased in the aluminum impurity layer 165 such that the recombination of electron is prevented and the back surface field (BSF) effect improving the collection efficiency of the generated carrier is further increased.

Hereinafter, various characteristics of a solar cell according to an exemplary embodiment of the present disclosure as compared with other comparative examples will be described in detail with reference to FIG. 4.

FIG. 4 is a table comparing an exemplary embodiment of the present disclosure with other comparative examples by measuring open circuit voltage (Voc), fill factor (FF), efficiency (Eff), and resistance (Rs).

Comparative example 1 illustrates a rear electrode formed by an aluminum-only paste, comparative example 2 illustrates a rear electrode formed by a mixed paste with a silicon powder of 12% and an aluminum powder of 88%, while the exemplary embodiment, as so denoted in the table of FIG. 4 illustrates a rear electrode formed by a silicon (Si)-aluminum (Al) eutectic alloy paste including a silicon (Si)-aluminum (Al) eutectic alloy powder composed of silicon of 12 at % and aluminum of 88 at %.

In the case of comparative example 1, open circuit voltage Voc is 630.5 mV, fill factor is 77.3%, efficiency is 18.48%, and resistance is 0.83 ohm/square.

In the case of comparative example 2, open circuit voltage Voc is 628.3 mV, fill factor is 73.0%, efficiency is 16.93%, and resistance is 1.88 ohm/square.

In the case of the exemplary embodiment, open circuit voltage Voc is 638.0 mV, fill factor is 77.5%, efficiency is 18.64%, and resistance is 0.75 ohm/square.

Thus, in comparing the exemplary embodiment with comparative example 1, in the exemplary embodiment as compared with comparative example 1, the open circuit voltage is increased by 8.5 mV, the fill factor is increased by 0.2%, and the efficiency is improved by 0.16%. In addition, the resistance is decreased by 0.08 ohm/square.

In comparing the exemplary embodiment with comparative example 2, in the exemplary embodiment as compared with comparative example 2, the open circuit voltage is increased by 9.7 mV, the fill factor is increased by 2.5%, and the efficiency is improved by 1.71%. In addition, the resistance is decreased by 1.13 ohm/square.

Therefore, in the exemplary embodiment as compared with comparative examples 1 and 2, the open circuit voltage and the fill factor are advantageously increased such that the efficiency is increased and the resistance is advantageously decreased.

While the present disclosure has been provided in connection with what is presently considered to be practical exemplary embodiments, it is to be understood that the teachings are not limited to the disclosed embodiments, but, on the contrary, they are intended to cover various modifications and equivalent arrangements included within the spirit and scope of the present disclosure.

What is claimed is:

1. A solar cell, comprising:
a semiconductive base layer having a first conductivity type;
a semiconductive emitter layer disposed on or above the base layer and having an opposed second conductivity type;
a front electrode disposed on or above the emitter layer;
a passivation layer disposed under the base layer and having a contact hole defined therein exposing the base layer; and
a rear electrode disposed under the passivation layer and connected with the base layer through the contact hole,
wherein the rear electrode comprises a silicon (Si)-aluminum (Al) eutectic alloy powder.

2. The solar cell of claim 1, wherein the rear electrode further comprises a glass frit.

3. The solar cell of claim 2, wherein the silicon (Si)-aluminum (Al) eutectic alloy powder is composed of silicon of about 12 at % and aluminum of about 88 at %.

4. The solar cell of claim 3, wherein the glass frit is made of any one of a lead silicate glass, a bismuth (Bi)-based glass, and a lithium-based glass.

5. The solar cell of claim 4, wherein the passivation layer is made of a silicon nitride-based compound and has a thickness of about 2000 to 5000 Å.

6. The solar cell of claim 1, further comprising a buffer layer having a negative charge interposed between the base layer and the passivation layer.

7. The solar cell of claim 6, wherein the buffer layer is made of any one of aluminum oxide (Al₂O₃) or an aluminum oxide nitride (AlON) and has a thickness of 50 to 500 521 .

8. The solar cell of claim 6, further comprising an aluminum impurity layer disposed in the base layer and contacting the rear electrode.

9. The solar cell of claim 1, wherein the rear electrode further comprises boron and a glass frit.

10. The solar cell of claim 9, wherein the silicon (Si)-aluminum (Al) eutectic alloy powder is composed of silicon of 12 at % and aluminum of 88 at %.

11. The solar cell of claim 10, wherein the glass frit is made of any one of a lead silicate glass, a bismuth (Bi)-based glass, and a lithium-based glass.

12. The solar cell of claim 1, wherein the passivation layer is made of a silicon nitride-based compound and has a thickness of 2000 to 5000 Å.

13. The solar cell of claim 12, further comprising a buffer layer having a negative charge interposed between the base layer and the passivation layer.

14. The solar cell of claim 13, wherein the buffer layer is made of any one of aluminum oxide (Al₂O₃) or an aluminum oxide nitride (AlON) and has a thickness of 50 to 500 Å.

15. The solar cell of claim 1, further comprising an aluminum impurity layer disposed in the base layer and contacting the rear electrode.
